(19) United States
(12) Patent Application Publication
(10) Pub. No.: US 2009/0302419 A1
(43) Pub. Date: Dec. 10, 2009

(54) METHOD OF MODIFYING SURFACE AREA AND ELECTRONIC DEVICE

(75) Inventors: Antonius L A M Kemmeren, Breda (NL); Freddy Roozeboom, Waalre (NL); Johan H. Klootwijk, Eindhoven (NL); Robertus A. M. Wolters, Eindhoven (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/720,322

(22) PCT Filed: Nov. 25, 2005
(86) PCT No.: PCT/IB2005/053905

§ 371 Date: Aug. 28, 2009

(30) Foreign Application Priority Data
Nov. 26, 2004 (EP) 04106120.1
Jan. 21, 2005 (EP) 05100364.8

(51) Int. Cl. H01L 27/06; H01L 21/02; H01L 21/302

(52) U.S. Cl. 257/531; 438/386; 438/694; 257/E27.011; 257/E21.214; 257/E21.003

(57) ABSTRACT

In the method a first layer, particularly of amorphous silicon, is deposited on the surface of a substrate with trenches. Part of this surface is covered with a protective layer. The first layer is thereafter maskless removed with a dry etching treatment on the substrate surface while it is kept within the trench.

The invention relates to a method of modifying surface area of a surface of a semiconductor substrate comprising a trench, comprising the steps of
applying a first layer on a surface of the substrate and in the trench and providing a surface modification treatment to the first layer to effect a surface modification.
   The invention also relates to a method of manufacturing an electronic device comprising the steps of modifying surface area in a trench.
   The invention further relates to an electronic device comprising a semiconductor substrate provided with a substantially planar surface and with a trench having an aperture in the substrate surface and having a textural trench surface.

Such a method and such a device are for instance known from U.S. Pat. No. 6,566,222. The surface modification treatment in the known device is the provision of hemispherical grain silicon, also referred to as HSG. In this method the first layer comprises a semiconductor material, which is amorphous or polycrystalline silicon in particular. The treatment therein substantially roughens the surface, so that a textured surface of crystalline grains is left. Several methods to do the treatment are known, including the etching of the polycrystalline silicon, as disclosed in EP546976 and the forming of a seed layer and conversion of the amorphous silicon layer in situ into crystalline grains. The latter conversion is generally carried out with a heat treatment.

As indicated in U.S. Pat. No. 6,566,222 it is preferable that the HSG is deposited only in the trenches and that the substrate surface is substantially planar, so as to be suitable for further deposition steps. The known method uses thereto the technique of chemical-mechanical polishing (CMP) of the substrate surface after completion of the HSG process, and particularly after that the trench has been completely filled. Generally, this filling comprises the steps of depositing a layer of dielectric material and a layer of electrically conducting material, which layers are deposited in a conformal manner. As a result, the trench comprises a capacitor, of which the surface is enlarged; dependent on the specific method and the grain size, the enlargement factor of the trench surface, and therewith of the capacity, is up about 2.5.

It is a disadvantage of the known method that it does not allow the provision of structures or specific zones in the semiconductor substrate prior the application of the surface modification treatment. If such structures are on the substrate surface, they would be destroyed in the CMP treatment. If such structures are provided in the substrate, their consitution is damaged by the provision of the first layer of a semiconductor material, and particularly by the provision of the first layer that is doped with suitable charge carriers so as to be electrically conductive. Protective layers could be used to protect such a surface structure, but this surface structure would be damaged in the CMP step. Alternatively, the CMP step would not lead to an adequate result as a consequence of the material differences between the protective layer and the first layer. Furthermore, the protective layer cannot extend onto the complete surface, as it is then difficult to provide a contact to the electrode defined in the modified first layer or in an electrically conductive layer thereon. And finally, the provision of such structures and/or the any surface zones needed thereto is carried out at higher temperatures than the provision of the HSG. As a result, the order of the processing cannot be reversed adequately.

It is therefore a first object of the invention to provide a method of modifying surface area of the kind described in the opening paragraph, in which the substrate surface is not provided with the surface modification and in which no use is made of chemical-mechanical polishing for a removal of the surface modification from the substrate surface. This object is achieved in that the method comprises the steps of:
applying a first layer on a surface of the substrate and in the trench;
removing the first layer from the surface of the substrate in an etching treatment, and
applying a surface modification treatment to effect a surface modification only in the trench.

The effective step of the invention is that the first layer is removed prior to the application of the surface modification treatment. As a result, this treatment is carried out only in the trench. The substrate surface is thus not exposed to the treatment and needs not to be removed by a relatively contaminating CMP treatment.

It is an advantage of the process of the invention that the process is shortened. In the known method, an edge zone of the trench was created by doping the first layer selectively. The edge zone thereto had to be sufficiently doped so as to reduce or even prevent the growth of the hemispherical grain silicon. This step can be left out in the method of the invention. Moreover, the CMP step of the known method that is carried out after filling, includes the polishing of a considerable layer thickness; e.g. not only the modified surface, but also any filling materials deposited in the trench and on the substrate surface, had to be removed.

It is a further advantage of the method of the invention that it allows a larger freedom to include various different structures in the substrate.

In a most preferred embodiment, the etching step is carried out maskless in the sense of self aligned. Due to the shape of the trench, the etching treatment can be carried out uniformly, and still the first layer in the trench will not be removed, or only to a little extent. Specifically, use is made of a dry etching technique, such as reactive ion etching or sputter etching.

Alternatively, the etching treatment may be carried out in that the etchant is provided selectively. Suitable techniques thereto include all printing techniques, including inkjet printing and microcontactprinting. Such printing techniques are suitably used in combination with a wet-chemical etchant.

Preferably, a portion of the substrate is covered with a protective layer prior to application of the trench and of the first layer. This allows that specific substrate zones are created below the protective layer prior to the application of the surface modification treatment. In the case that the first layer is doped with an n-type dopant, p-type doped substrate zones as well as substrate zones that are substantially free of charge carriers need to be protected. A suitable protective layer that is above to withstand the temperatures used in the surface modification treatment is for instance silicon nitride or silicon oxide.

A particular example of such a substrate zone free of charge carriers is the substrate type known as high-resistive semiconductor material, and particularly high-resistive silicon. This semiconductor material is treated so as to have an amorphous top layer, or irradiated with electron beam or the like to modify the inherent structure of the silicon and increase the resistivity to a value in the order of at least 500 Ohm. centimetre and preferably even 1,000 Ohm.cm or more. In that manner, the substrate can be considered to be sufficiently electrically insulating to act as a support for inductors.

It is a second object of the invention to provide a method of manufacturing a semiconductor device. This is achieved in a method with the steps of:
modifying surface area in the trench as claimed in any of the claims 1-4, wherein the modified surface is electrically conducting;
depositing a dielectric material in the trench and on the substrate surface
depositing an electrode material on top of the dielectric material;
patterning the dielectric and the electrode material on the substrate surface to provide electrical connections to a first electrode defined in the modified surface area of the trench and to a second electrode defined in the electrode material in the trench.

Particularly, with this method it is possible to provide the trench with an enlarged trench surface and provide contacts to the electrodes op the substrate surfaces. In that manner these contacts may be opened with conventional photolithography and such that the contact resistance is not too high or only acceptable after a plurality of additional process steps.

Preferably, use is made of a first layer of a semiconductor material that is doped with charge carriers so as to have sufficient electrical conductivity. Alternatively, an additional electrode layer may be applied on top of the modified surface in a conformal manner. Suitable electrode materials include noble metals, conducting oxides and conducting nitrides. Particularly a conducting nitride such as TiN, or a noble metal such as Pt or Au is found to have acceptable properties, in view of the adhesion, the conformal deposition and the thickness.

The dielectric layer, and also any conducting layer applied on the modified surface, is preferably deposited with a technique allowing deposition in a kinetically determined regime. Particularly, low pressure chemical vapour deposition (LPCVD) and atomic layer deposition (ALD) are suitable techniques. The dielectric layer may be a conventional dielectric material, such as an oxide or a nitride or a combination thereof, but alternatively be a dielectric material with a higher dielectric constant, also known as high-K dielectrics. Such high-K dielectrics require specific processing, such as for instance the repeated deposition of monolayers of different composition on the textured surface as known from U.S. Pat. No. 6,780,704.

In a further embodiment, use is made of a solid-state electrolyte as the dielectric material. The resulting structure is then a battery. It has been found that solid-state electrolytes can be deposited in trenches so as to enhance the surface area, as is described in the non-prepublished PCT patent application WO IB2004/051483 (PHNL040740) of the present application, that is herein included by reference. With the use of the present technique, a battery can be suitably provided.

It is a third object of the invention to provide a device in which the substrate comprises both a trench structure with an increased surface area and another substrate structure.

This third object is achieved in that device comprises a semiconductor substrate provided with a substantially planar surface and with a trench having an aperture in the substrate surface and having a textural trench surface, which substrate is further provided with a substrate zone adjacent to the trench, in and/or on which substrate zone an electric element is defined.

The present device includes the functionality of a capacitor or battery with a high capacitance density in addition to other structures in which a non-doped substrate region is needed. Examples of such structures include inductors, as well as transistors and pin-diodes in which the substrate region is a vital part, i.e. the channel. The combination of such structures within one device is suitable to provide the often large-area functions locally and very near to advanced semiconductor devices that are in need of such functions. Often, the quality of the advanced semiconductor devices is so high that the other functions and the interconnects outside the semiconductor devices are limiting to the performance of the overall device. The provision of the functions locally first of all reduces the interconnect length.

Moreover, the resulting miniaturisation of the capacitance increase leads to a further miniaturisation of the device. On the one hand, miniaturisation leads to cost price reduction and this makes the device highly competitive with solutions based on discrete components and with solutions based on a laminate. On the other hand, the size reduction reduces packaging problems. With a decrease in size, the absolute value of the stresses resulting from differences in coefficients of thermal expansion of the carrier and the device are reduced. Hence, the risk that cracks are initated, decreases. It must be understood that the invention allows here a double gain. As the capacitors made in the invention have a higher density, they may thus be smaller and/or may be larger. When such larger capacitors are present in the devices, they are not needed on the carrier. Hence, any connections needed in the prior art for the connection to capacitors on the carrier, can be left out. This again reduces again the size, as the size of contact pads, at least two per capacitor, is substantial.

Additionally, it is particularly preferred that the substrate comprises through-holes filled with electrically conductive material. These through-holes allow the provision of contact pads for external contacting at the bottom surface facing away from the capacitors. Therewith it enables the use of the top surface for the mounting of additional components such as integrated circuits, power amplifiers, filters and other devices. It is particularly suitable that at least some of these through-holes are designed so as to allow dissipation of heat.

In line with the above mentioned, it is particularly preferred that the device of the invention is used as part of an assembly with a semiconductor device. Both the flip-chip technology and the wirebonding technology may be used for this purpose. It is not excluded herein that the semiconductor device overlies the capacitor structure in the substrate of the invention. In case of a flip-chip device, this is even found to be advantageous, as a very direct and short connection may be made between the semiconductor device and the capacitor. The capacitor structure can herein function as a memory, but also as a storage capacitor or as a filtering capacitor. The latter purposes are understood to be highly suitable, in line with the large capacitance available. In such a system, it may be very suitable to include elements in the device for protection against electrostatic discharge. Such components are usually diodes. Such protection is needed not only for discharge during use, but also for discharge during the manufacture. Additional components to be integrated in and on the substrate are for instance switches.

These and other aspects of the invention will be further elucidated with reference to the drawings, in which:

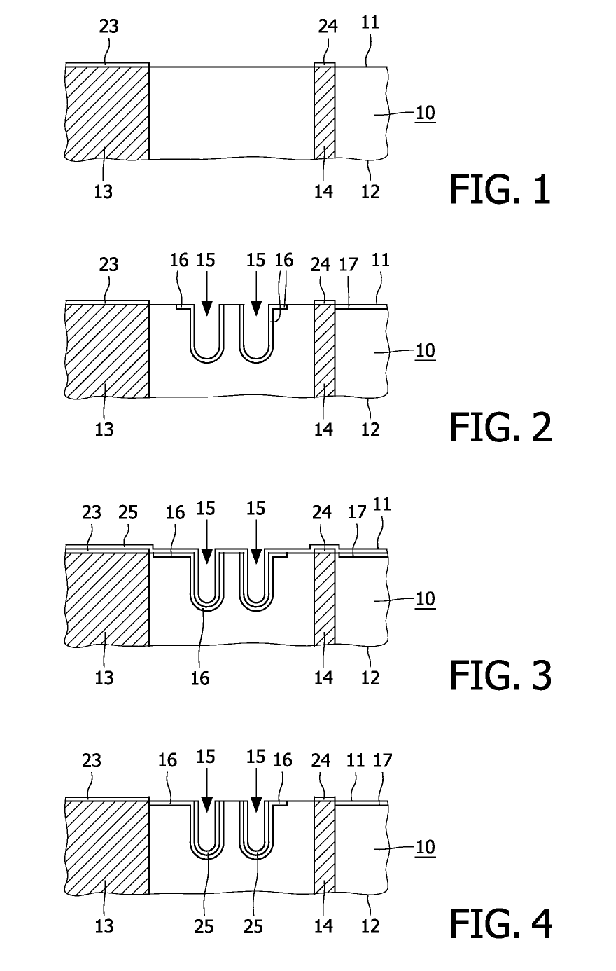

FIGS. 1-6 show diagrammatically cross-sectional views of several stages in the method of the invention, and

FIG. 7 shows in diagrammatical cross-sectional view the device of the invention.

The Figures are not drawn to scale. Equal reference numerals in different Figures refer to like elements. The Figures are merely illustrative and should not be understood as limiting to the invention.

FIGS. 1 to 6 show diagrammatically cross-sectional view of several stages in the method of the invention. In the first stage, shown in FIG. 1, a substrate 10 is provided with a first side 11 and an opposite second side 12. The substrate 10 is provided with substrate regions 13, 14. These regions are in the present example high-ohmic and have been treated with irradiation of electron beams to increase the resistivity of the substrate regions 13,14. The high-ohmic region 14 is defined between areas in which separate capacitors are to be defined. It aims at preventing any parasitic currents as much as possible. Suitably, the resistivity of the substrate in these regions is in the range of 0.5 to 3 kΩ.cm. The regions 13,14 are protected on the first side 11 by masks 23,24. A suitable mask 23,24 is a layer of silicon nitride. The resistivity of the other portions of the substrate 10 was in the order of 1 to 5 mΩ.cm, FIG. 2 shows the substrate 10 after etching of trenches 15 and after doping of the substrate with charge carriers to define conducting areas 16, 17 as electrodes. The trenches 15 were etched at room temperature in an ASE™ Inductively Coupled Plasma (ICP) reactor of STS. Typical etching conditions were 12 to 16 mTorr pressure and 20° C. chuck temperature, yielding etch rates of around 0.6 μm/min. With this process the trenches are characterized by a smooth pore wall with a rounded bottom and a pore depth uniformity of more than 97%. The trenches 15 with a mask opening of 1.5 μm diameter led to a depth up to 40 μm and a diameter of 1.5 to 2 μm. Other trenches had a with a mask opening of 10 μm diameter, which led to a depth of 200 μm and a diameter of 12 μm. The pore depth is slightly larger than the mask opening due to underetch. In the doping step, use was made of a P indiffusion from a pre-deposited phosphorus silicate glass layer. Alternatively, use can be made of gas phase doping with phosphine. The silicate layer was then removed by wet etching in 1% (v/v) HF. The mask 23,24 was herein used as a doping mask. Alternatively, a separate mask could be used.

FIG. 3 shows the substrate 10 after provision of a first layer 25. In this case, the first layer comprises amorphous silicon in a thickness of 10 nm. The first layer 25 is deposited maskless in a Phase Enhanced Chemical Vapour Deposition (PECVD) process at about 300° C. and covers the surface of the first side 11 of the substrate 10 and the inner surface of the trenches 15. The amorphous silicon layer 25 is in situ doped.

FIG. 4 shows the substrate 10 after a subsequent step, in which the first layer 25 is partially removed. This is achieved without a mask. In this example, use is made of reactive ion etching with an argon plasma. Generally, any plasma will work that is based on physical etching only, and wherein the chemical etching is inactive. With chemical etching is meant herein any kind of etching in which a reactive component in the plasma etches the substrate by means of a chemical or dissolution reaction with the substrate material. Chemical etching would lead to contamination of the trenches.

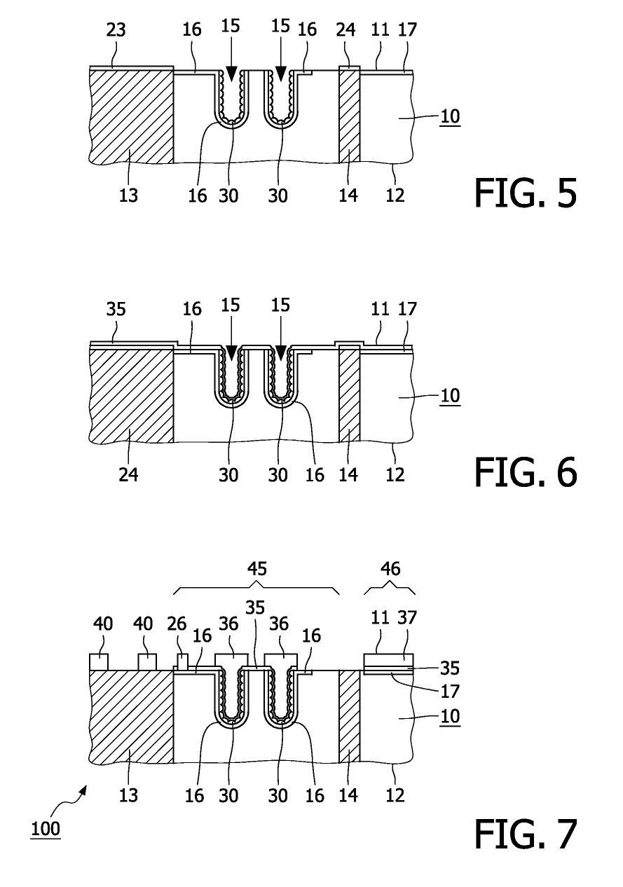

FIG. 5 shows the substrate after a further step, in which the first layer 25 is converted into a layer 30 with grains. Use is made herein of a process known per se as hemispherical silicon growth. This process starts with low pressure chemical vapour deposition (LPCVD) of nucleation grains at a pressure in the range of 100-1000 mTorr. The growth of the grains is then in effect a recrystallisation of the deposited amorphous silicon layer 25. The area enhancement factor of the grains is between 1,3 and 3, which is dependent on the grain size.

FIG. 6 shows a subsequent step in which a dielectric 35 is deposited conformally with the formed grained structure in the trenches. Use is made of atomic layer deposition (ALD) for this step, as known to the skilled person. Alternatively, use can be made of any other chemical vapour deposition technique. It will be deposited in a desired thickness, so as to prevent the existence of through-holes and to provide a sufficient breakdown voltage. Good results have been obtained with a dielectric layer 35 comprising a stack of oxide, nitride and oxide layers.

FIG. 7 shows the resulting device 100, after a number of further steps have been carried out. First of all, the trenches 15 have been filled with conductive material 36, in this case doped polysilicon. This polysilicon is deposited in an LPCVD process as well. Herewith, a capacitor 45 is formed with the conductive zone 16 as the first electrode and the polysilicon layer 36 as the second electrode. The polysilicon also forms a top electrode 37 for a second capacitor 47 that uses the conducting zone 17 as bottom electrode. The first electrode 16 of the trench capacitor 45 is contacted through a contact plug 26 that extends through the dielectric layer 35. It is located at an area adjacent to the trench.

Additionally, in FIG. 7 the masks 23,24 of silicon nitride have been removed. A conductor pattern 40 is defined on the substrate region 13, which functions as an inductor. This conductor pattern may include further interconnects, bond pad structures and the like.

If desired, the processing can be continued with, for instance, the provision of vertical interconnects from the first side 11 to the second side 12 of the substrate 10. Suitably, use is made of trenches that are defined simultaneously with the trenches 15, but with a larger diameter. These may then be opened from the second side 12, for instance by wet-chemical etching or thinning of the substrate 10, or a combination thereof.

Suitably, the capacitance can be further increased in that a stacked capacitor is provided in the trenches 15. Then an electrically conductive layer is deposited by LPCVD onto the dielectric layer 35 in a conformal manner that is chosen to be stable in a subsequent layer deposition of LPCVD or ALD. A good example is TiN. This can be deposited in a plasma assisted ALD cycle with a first step of TiCl4 deposition, then an Ar purge and hereafter a plasma exposure (10 mTorr H₂ and 1 mTorr N₂). Alternatives to this process can be envisaged by the skilled person.

1. A method of modifying surface area in a trench in a semiconductor substrate comprising the steps of: applying a first layer on a surface of the substrate and in the trench; removing the first layer from the surface of the substrate in an etching treatment, and providing a surface modification treatment to effect a surface modification only in the trench

2. A method as claimed in claim 1, wherein the etching treatment is carried out without a mask.

3. A method as claimed in claim 2, wherein the etching treatment is a dry etching technique.

4. A method as claimed in claim 1, wherein a portion of the substrate is covered with a protective layer prior to application of the trench and of the first layer.

5. A method of manufacturing an electronic device comprising the steps of: modifying surface area in trench as claimed in claim 1, wherein the modified surface is electrically conducting; depositing a dielectric material in the trench and on the substrate surface depositing an electrode material on top of the dielectric material; patterning the dielectric and the electrode material on the substrate surface to provide electrical connections to a first electrode defined in the modified surface area of the trench and to a second electrode defined in the electrode material in the trench.

6. A method as claimed in claim 5, wherein the dielectric is a solid state electrolyte and the structure of the first electrode, the dielectric and the second electrode constitutes a battery.

7. An electronic device comprising a semiconductor substrate provided with a substantially planar surface and with a trench having an aperture in the substrate surface and having a textural trench surface, which substrate is further provided with a substrate zone adjacent to the trench, in and/or on which substrate zone an electric element is defined.

8. An electronic device as claimed in claim 7, wherein the textural shape of the trench surface is constituted by hemispheral grown semiconductor material.

9. An electronic device as claimed in claim 7, wherein the substrate zone is substantially free of charge carriers.

10. An electronic device as claimed in claim 9, wherein the electrical element is an inductor.

11. An electronic device as claimed in claim 9, wherein the electrical element is a semiconductor element and the substrate zone acts as a channel or insulating zone in the semiconductor element.

12. An assembly comprising the electronic device of claim 7 and a semiconductor element assembled to it.
